(19) United States
(12) Patent Application Publication
(10) Pub. No.: US 2010/0275836 A1
(43) Pub. Date: Nov. 4, 2010

(54) METHOD FOR GROWING GROUP III NITRIDE CRYSTAL

(75) Inventors: Fumitaka Sato, Hyogo (JP); Seiji Nakahata, Hyogo (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi, Osaka (JP)

(21) Appl. No.: 12/812,338

(22) PCT Filed: Jan. 8, 2009
(86) PCT No.: PCT/JP2009/050110

§ 371 Date: Jul. 9, 2010

(30) Foreign Application Priority Data
Jan. 16, 2008 (JP) 2008-006854

(51) Int. Cl. C30B 23/04

(52) U.S. Cl. 117/97

(57) ABSTRACT

The present method for growing group III nitride crystal includes the steps of: preparing a substrate including group III nitride seed crystal constituting one main surface thereof; forming a plurality of facets on the main surface of the substrate through vapor phase etching; and growing group III nitride crystal on the main surface on which the facets are formed. In this way, group III nitride crystal having a low dislocation density can be obtained readily and efficiently.

### TECHNICAL FIELD

The present invention relates to a method for growing group III nitride crystal having a low dislocation density.

### BACKGROUND ART

Group III nitride crystal such as AlₓGa₁₋ₓN (0≦x≦1) crystal is suitably used for various types of semiconductor device such as a light emitting device and an electronic device. For improved characteristics of these semiconductor devices, a demand arises in group III nitride crystal having a low dislocation density.

As a method for growing group III nitride crystal having a low dislocation density, an ELO (epitaxial lateral overgrowth) method is disclosed (for example, see International Publication No. WO98/047170 (Patent Document 1)). In the ELO method, a mask layer having an opening is formed on a substrate, and group III nitride crystal is grown laterally from the opening onto the mask layer.

Patent Document 1: International Publication No. WO98/047170

### DISCLOSURE OF THE INVENTION

### Problems to be Solved by the Invention

Although the ELO method disclosed in International Publication No. WO98/047170 (Patent Document 1) allows for reduced dislocation density in the group III nitride crystal to be grown, the mask layer having the opening needs to be formed. Hence, processes are complicated. The ELO method is thus disadvantageous in productivity and cost effectiveness.

In view of this, an object of the present invention is to provide a method for growing group III nitride crystal having a low dislocation density readily and efficiently.

### Means for Solving the Problems

The present invention provides a method for growing group III nitride crystal, including the steps of: preparing a substrate including a group III nitride seed crystal constituting one main surface thereof; forming a plurality of facets through vapor phase etching on the main surface of the substrate; and growing group III nitride crystal on the main surface on which the facets are formed.

In the method according to the present invention for growing group III nitride crystal, the main surface may have an off-orientation angle of 10° or smaller relative to a (0001) plane of the group III nitride seed crystal, and the facets include at least one geometrically equivalent crystal plane selected from a group consisting of {11-2m} planes and {10-1n} planes, m being a positive integer, n being a positive integer. In addition, the vapor phase etching may be performed using at least one gas selected from a group consisting of HCl gas, Cl₂ gas, and H₂ gas. Further, the main surface on which the facets are formed may have an average roughness Ra of 1 μm or greater but 1 mm or smaller. Furthermore, after the vapor phase etching, the substrate may have a thickness of 300 μm or smaller. Moreover, after the step of forming the plurality of facets on the main surface of the substrate, the step of growing group III nitride crystal on the main surface on which the facets are formed is performed uninterruptedly without moving the substrate.

### EFFECTS OF THE INVENTION

According to the present invention, there can be provided a method for readily and efficiently growing group III nitride crystal having a low dislocation density.

### BRIEF DESCRIPTION OF THE DRAWINGS

FIG. 1 is a schematic cross sectional view showing one embodiment of a method for growing group III nitride crystal according to the present invention. FIG. 1(a) illustrates a substrate preparation step, FIG. 1(b) illustrates a facet formation step, and FIG. 1(c) illustrates a group III nitride crystal growth step.

FIG. 2 is an enlarged view of a II portion in FIG. 1(b).

FIG. 3 is an enlarged view of a III portion in FIG. 1(c).

FIG. 4A is a schematic cross sectional view showing one embodiment of the facet formation step of the method for growing group III nitride crystal in the present invention, using an HYPE method.

FIG. 4B is a schematic cross sectional view showing one embodiment of the group III nitride crystal growth step of the method for growing group III nitride crystal in the present invention, using the HVPE method.

### DESCRIPTION OF THE REFERENCE SIGNS

1: HCl gas; 2: group III element raw material; 3: group III element raw material gas; 4: nitride raw material gas; 5, 8: exhaust gas; 7: etching gas; 10: substrate; 10a: group III nitride seed crystal; 10b: underlying substrate; 10m: main surface; 10ms, 10mt, 10mu: facet; 10n: (0001) plane; 20: group III nitride crystal; 100: HYPE apparatus; 110: reaction chamber; 111: first gas introduction pipe; 112: second gas introduction pipe; 113: third gas introduction pipe; 115: gas discharge pipe; 119: substrate holder; 120: group III element raw material gas generation chamber; 121: group III element raw material boat; 131, 132, 133: heater.

### BEST MODES FOR CARRYING OUT THE INVENTION

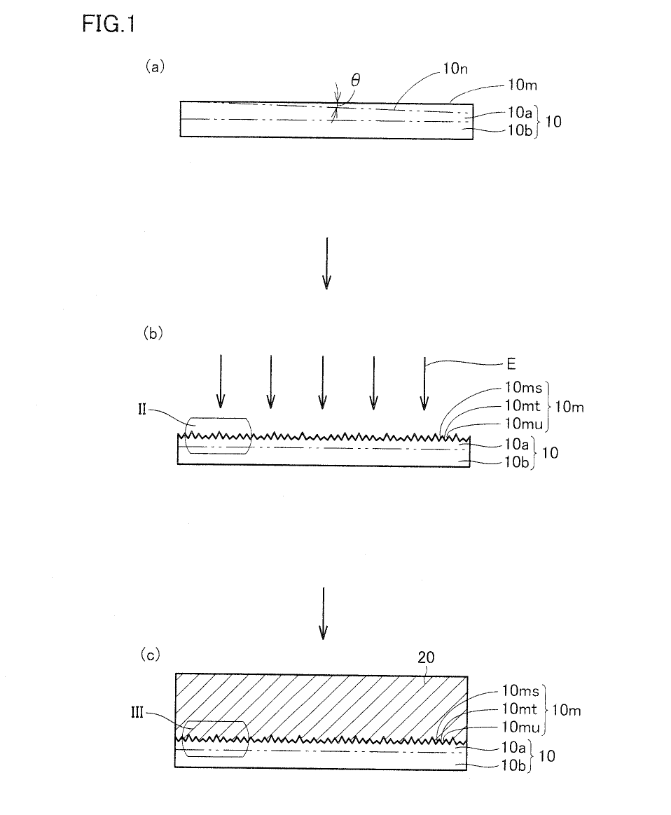

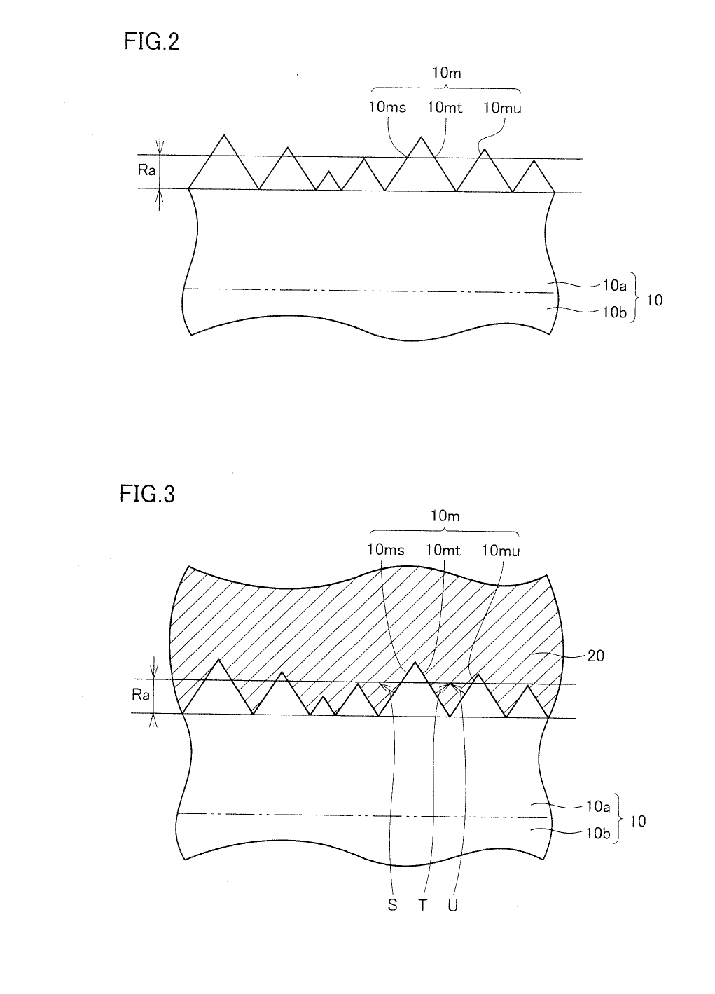

Referring to FIG. 1-FIG. 3, a method for growing group III nitride crystal in one embodiment of the present invention includes a step (FIG. 1(a)) of preparing a substrate 10 including group III nitride seed crystal 10a constituting one main surface 10m thereof; a step (FIG. 1(b), FIG. 2) of forming a plurality of facets 10ms, 10mt, 10mu on main surface 10m of substrate 10 through vapor phase etching; and a step (FIG. 1(c), FIG. 3) of growing group III nitride crystal 20 on main surface 10m on which facet 10ms, 10mt, 10mu are formed.

According to the method for growing group III nitride crystal in the present embodiment, group III nitride crystal 20 is grown on the plurality of facets 10ms, 10mt, 10mu formed on main surface 10m of substrate 10. Here, directions in which the crystal is grown on facets 10ms, 10mt, 10mu and the directions in which dislocations are propagated (directions respectively indicated by arrows S, T, and U in FIG. 3) are directions substantially perpendicular to facets 10ms, 10mt, 10mu, respectively. This allows reduced dislocations propagating in the direction substantially perpendicular to main surface 10m in group III nitride crystal 20.

In the crystal growing on facets facing each other (for example, facet 10mt and facet 10mu), directions in which dislocations are propagated (the directions indicated by arrows T and U) are opposite to each other. Accordingly, the dislocations thus propagated impinge on one another (impinge as indicated by arrows T and U in FIG. 3, for example). By the impingement, dislocations having opposite signs of the Burgers vector and having the same magnitude are vanished. Dislocations having not been vanished are absorbed in regions in which the facets facing each other meet. In this way, dislocation density is reduced in group III nitride crystal 20.

Referring to FIG. 1-FIG. 3, the method for growing group III nitride crystal in the present embodiment will be described more in detail. First, referring to FIG. 1(a), substrate 10 is prepared which includes group III nitride seed crystal 10a constituting one main surface 10m thereof (substrate preparation step). Between group III nitride seed crystal 10a and group III nitride crystal to be grown, mismatch is small in their crystal lattices. In particular, when types and densities of constituent atoms of the group III nitride seed crystal and the group III nitride crystal to be grown are the same, crystal lattices therebetween match with each other. As such, by employing substrate 10 including group III nitride seed crystal 10a constituting one main surface 10m, group III nitride crystal 20 having a low dislocation density and high crystallinity can be grown on main surface 10m.

Here, substrate 10 is not particularly limited as long as it includes group III nitride seed crystal 10a constituting one main surface 10m. Substrate 10 may be a free-standing substrate entirely formed of group III nitride seed crystal 10a. Alternatively, substrate 10 may be a template substrate in which an underlying substrate 10b has a layer of group III nitride seed crystal 10a formed thereon. An exemplary substrate 10 entirely formed of group III nitride seed crystal 10a is a GaN substrate, an AlN substrate, an AlₓGa₁₋ₓN (0<x<1) substrate, or the like. An exemplary substrate 10 in which underlying substrate 10b has the layer of group III nitride seed crystal 10a formed thereon is a GaN/sapphire substrate (substrate in which a sapphire substrate has GaN seed crystal formed thereon; the same is applied in the description below), a GaN/SiC substrate (substrate in which an SiC substrate has GaN seed crystal formed thereon; the same is applied in the description below); a GaN/Si substrate (substrate in which an Si substrate has GaN seed crystal formed thereon; the same is applied in the description below); a GaN/GaAs substrate (a substrate in which a GaAs substrate has GaN seed crystal formed thereon; the same is applied in the description below); a GaN/GaP substrate (a substrate in which a GaP substrate has GaN seed crystal formed thereon; the same is applied in the description below); a GaN/InP substrate (a substrate in which an InP substrate has GaN seed crystal formed thereon; the same is applied in the description below), or the like.

Next, referring to FIGS. 1(b) and 2, the plurality of facets 10ms, 10mt, 10mu are formed on main surface 10m of substrate 10 through vapor phase etching (facet formation step). By forming the plurality of facets 10ms, 10mt, 10mu on main surface 10m, the directions in which group III nitride crystal 20 grows on facets 10ms, 10mt, 10mu of main surface 10m and the directions in which the dislocations are propagated are substantially perpendicular to facets 10ms, 10mt, 10mu respectively, resulting in reduced dislocations propagating in the direction substantially perpendicular to main surface 10m. In the crystal growing on facets facing each other (for example, facet 10mt and facet 10mu), dislocations having opposite signs of the Burgers vector and the same magnitude impinge on one another and are accordingly vanished. Dislocations having not been vanished are absorbed in a region in which the facets facing each other meet. In this way, dislocation density is reduced in group III nitride crystal 20.

Here, group III nitride seed crystal 10a has a wurtzite-type crystal structure in a hexagonal system. Hence, the plurality of facets 10ms, 10mt, 10mu provide an irregular surface having a plurality of projections each shaped in a multi-sided pyramid. Here, the multi-sided pyramid is not particularly limited but one with a six-sided pyramid, a four-sided pyramid, a three-sided pyramid, a twelve-sided pyramid, or the like can be readily formed.

Meanwhile, the plurality of facets 10ms, 10mt, 10mu on main surface 10m of substrate 10 are formed using vapor phase etching. The vapor phase etching provides the facets with surfaces in good condition. The surfaces in good condition herein refer to surfaces having less impurity, which is included due to surface treatment, and exhibiting an intended crystal plane. If polishing processing and liquid phase etching are employed, selectivity in etching is bad and impurity is likely to be included therein, whereby facets with surfaces in good condition cannot be obtained. This makes it difficult to reduce dislocation density in group III nitride crystal to be grown.

The gas used in the vapor phase etching is not particularly limited as long as facets with surfaces in good condition are obtained, but in order to efficiently etch the group III nitride seed crystal, it is preferable to use at least one gas selected from a group consisting of HCl gas, Cl₂ gas, and H₂ gas. Here, HCl gas and H₂ gas are preferable for etching of GaN seed crystal, AlₓGa₁₋ₓN seed crystal having a low Al composition (for example, 0<x<0.5), or the like. Cl₂ gas is preferable for etching of AlN seed crystal, an AlₓGa₁₋ₓN seed crystal having a high Al composition (for example, 0.5≦x<1), or the like. Alternatively, the above-exemplified etching gases can be used together.

For efficient etching of the group III nitride seed crystal, the partial pressure of the etching gas is preferably 0.1 Pa or greater but 100 kPa or smaller, the etching temperature is preferably 700° C. or higher but 1200° C. or lower, and the etching time is preferably 1 minute or longer but 180 minute or shorter.

Next, referring to FIGS. 1(c) and 3, group III nitride crystal is grown on main surface 10m on which facets 10ms, 10mt, 10mu are formed (group III nitride crystal growth step). As a result of the crystal growth, group III nitride crystal 20 is grown on the plurality of facets 10ms, 10mt, 10mu formed on main surface 10m of substrate 10. Here, the directions in which crystal is grown on facets 10ms, 10mt, 10mu and the directions in which dislocations are propagated (directions respectively indicated by arrows S, T, and U in FIG. 3) are substantially perpendicular to facets 10ms, 10mt, 10mu, respectively. In this way, dislocations propagating in the direction substantially perpendicular to main surface 10m are reduced in group III nitride crystal 20.

Further, in the crystal growing on facets facing each other (for example, facet 10mt and facet 10mu), the directions in which dislocations are propagated (directions indicated by arrows T and U) are opposite to each other. Hence, the dislocations propagated impinge on one another (impinge as indicated by arrows T and U in FIG. 3, for example). By the impingement, dislocations having opposite signs of the Burgers vector and the same magnitude are vanished. Dislocations having not been vanished are absorbed in a region in which the facets facing each other meet. In this way, dislocation density is reduced in group III nitride crystal 20.

Here, the method for growing group III nitride crystal 20 is not particularly limited. Methods usable therefor are vapor phase methods such as an HVPE (Hydride Vapor Phase Epitaxy) method, an MOCVD (Metal-Organic Chemical Vapor Deposition) method, and a sublimation method; liquid phase methods such as a solution method and a flux method; and the like. Among these methods for growing crystal, the vapor phase methods are preferable because crystal can be grown uninterruptedly after the vapor phase etching. Further, among the vapor phase methods, the HVPE method is more preferable because it allows for fast growth of crystal.

Referring to FIG. 1(a), in the method for growing group III nitride crystal in the present embodiment, main surface 10m of substrate 10 preferably has an off-orientation angle θ of 10° or smaller relative to (0001) plane 10n of group III nitride seed crystal 10a, and each of facets 10ms, 10mt, 10mu preferably includes at least one geometrically equivalent crystal plane selected from a group consisting of {11-2 m} planes (m is a positive integer) and {10-1n} planes (n is a positive integer). Here, m and n may be the same positive integer or different positive integers.

Since main surface 10m of substrate 10 has an off-orientation angle θ of 10° or smaller relative to the (0001) plane, which is a stable crystal plane of group III nitride seed crystal 10a, group III nitride crystal 20 having a low dislocation density can be grown stably on such a main surface 10m.

Further, each of facets 10ms, 10mt, 10mu includes at least one geometrically equivalent crystal plane selected from the group consisting of the {11-2 m} planes (m is a positive integer) and the {10-1n} planes (n is a positive integer), which are stable crystal planes of group III nitride seed crystal 10a. Hence, group III nitride crystal 20 having a low dislocation density can be stably grown on facets 10ms, 10mt, 10mu. Here, the {11-2 m} planes refer to a (11-2m) plane and a crystal plane geometrically equivalent to the (11-2m) plane, whereas the 110-1111 planes refer to a (10-1n) plane and a crystal plane geometrically equivalent to the (10-1n) plane.

Here, the (0001) plane of group III nitride seed crystal 10a, the plane orientation of the main surface, and the off-orientation angle relative to the (0001) plane, as well as the plane orientations of the facets can be measured through observation on the substrate with X-ray diffraction, an SEM (scanning electron microscope), and a laser microscope.

Referring to FIG. 2, in the method for growing group III nitride crystal in the present embodiment, main surface 10m having facets 10ms, 10mt, 10mu formed thereon preferably has an average roughness Ra of 1 μm or greater but 1 mm or smaller. Here, average roughness Ra of main surface 10m refers to an arithmetic average roughness Ra defined in the JIS B 0601. Specifically, from a roughness profile, a reference area is extracted in a direction of its average surface. The absolute values of distances (deviations) from the average surface of the portion thus extracted to the roughness profile are summed up and are averaged out by the reference area. Average roughness Ra is a value obtained in this way. Further, average roughness Ra can be measured using a 3D-SEM (three-dimensional scanning electron microscope), a laser microscope, or the like. When average roughness Ra of main surface 10m is smaller than 1 μm, the total number of facets is larger but an average area for one facet is smaller, which decreases the effect of reducing dislocations. Similarly, when average roughness Ra of main surface 10m is more than 1 mm, an average area for one facet is larger but the total number of facets is smaller, which decreases the effect of reducing dislocations.

In the method for growing group III nitride crystal in the present embodiment, the substrate having been through the vapor phase etching preferably has a thickness of 300 μm or smaller. If a substrate having a thickness of more than 300 μm is employed, stress/strain is large between the substrate and the group III nitride crystal due to a difference in thermal expansion coefficient therebetween upon growing the group III nitride crystal on the substrate or cooling it down after the growth thereof. Accordingly, breakage and cracks are likely to occur in the substrate and the group III nitride crystal upon the crystal growth or the cooling after the crystal growth. A substrate with a smaller thickness allows for more relaxation of stress/strain imposed between the substrate and the group III nitride crystal due to the difference in thermal expansion coefficient therebetween upon the growth of group III nitride crystal on the substrate and upon cooling after the growth thereof. In view of this, the substrate having been through the vapor phase etching more preferably has a thickness of 200 μm or smaller, and further preferably has a thickness of 100 μm or smaller.

Referring to FIG. 1, in the method for growing group III nitride crystal in the present embodiment, it is preferable that after the step (FIG. 1(b)) of forming the plurality of facets 10ms, 10mt, 10mu on main surface 10m of substrate 10 using the vapor phase etching, the step (FIG. 1(c)) of growing group III nitride crystal 20 on main surface 10m on which facets 10ms, 10mt, 10mu are formed be performed uninterruptedly without moving substrate 10. In view of this, it is preferable to employ a vapor phase method to grow group III nitride crystal 20. The vapor phase method is not particularly limited, but methods preferably used therefor are the HVPE (Hydride Vapor Phase Epitaxy) method, the MOCVD (Metal-Organic Chemical Vapor Deposition) method, an MBE (Molecular Beam Epitaxy) method, and the like. Among them, the HVPE method is more preferable because it allows for fast growth of crystal.

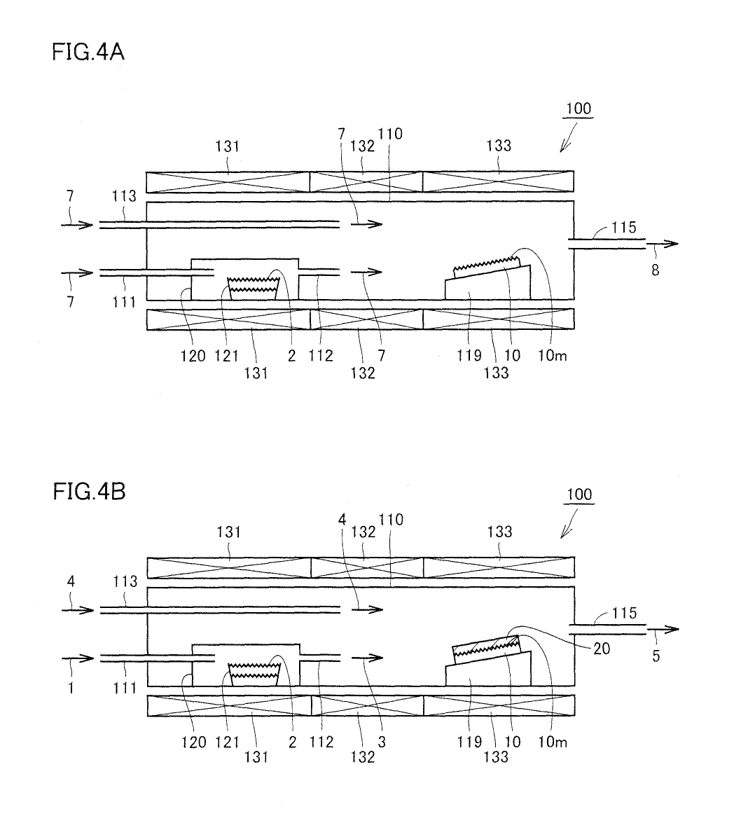

For growth of group III nitride crystal 20 using the HVPE method, for example, an HVPE apparatus 100 shown in FIG. 4B is used. HVPE apparatus 100 includes a reaction chamber 110, a group III element raw material gas generation chamber 120, and heaters 131, 132, 133 for heating reaction chamber 110 and group III element raw material gas generation chamber 120. In reaction chamber 110 and group III element raw material gas generation chamber 120, a first gas introduction pipe 111 is installed to introduce HCl gas 1 into group III element raw material gas generation chamber 120. In group III element raw material gas generation chamber 120, there is provided a group III element raw material boat 121 containing a group III element raw material 2 therein. In addition, in group III element raw material gas generation chamber 120, a second gas introduction pipe 112 is installed to introduce generated group III element raw material gas 3 into reaction chamber 110. In reaction chamber 110, a third gas introduction pipe 113 is installed to introduce nitride raw material gas 4 into reaction chamber 110 and a gas discharge pipe 115 is installed to discharge exhaust gas 5 from reaction chamber 110 to outside reaction chamber 110. Further, in reaction chamber 110, a substrate holder 119 is provided on which substrate 10 is placed for growth of group III nitride crystal 20.

Referring to FIG. 4A, first, HVPE apparatus 100 described above is employed to form the plurality of facets 10ms, 10mt, 10mu on main surface 10m of substrate 10 through vapor phase etching. Specifically, substrate 10 is first placed on substrate holder 119 in reaction chamber 110. Then, etching gas 7 is introduced into reaction chamber 110 via first and second gas introduction pipes 111, 112 or via third gas introduction pipe 113, or via first and second gas introduction pipes 111, 112 and third gas introduction pipe 113. On this occasion, substrate 10 is being heated by heater 133. Etching gas 7 thus introduced etches main surface 10m of substrate 10 to form the plurality of facets. Exhaust gas 8 in reaction chamber 110 after the etching is discharged via gas discharge pipe 115. At the time of vapor phase etching, the substrate preferably has a temperature (hereinafter, also referred to as “etching temperature”) of 700° C. or higher but 1200° C. or lower, and more preferably has a temperature of 950° C. or higher but 1050° C. or lower for effective etching, although the temperature is not particularly limited. Likewise, the partial pressure of etching gas 7 is not particularly limited but is preferably 0.1 Pa or greater but 100 kPa or smaller and is more preferably 10 Pa or higher but 10 kPa or smaller for effective etching.

Here, etching gas 7 is not particularly limited but is preferably at least one gas selected from a group consisting of HCl gas, Cl₂ gas, and H₂ gas for efficient etching of group III nitride seed crystal included in at least main surface 10m of substrate 10. Here, in the case where HCl gas is introduced as etching gas 7 via first and second gas introduction pipes 111, 112, the HCl gas needs to be introduced into reaction chamber 110 so that the it does not react with group III element raw material 2. This can be attained when group III element raw material 2 is not placed in group III element raw material gas generation chamber 120 or group III element raw material gas generation chamber 120 is not heated.

Referring to FIG. 4B, uninterruptedly thereafter, group III nitride crystal 20 is grown on main surface 10m of substrate 10 using the HYPE method without moving substrate 10 having main surface 10m on which the facets are formed. Specifically, group III element raw material boat 121 containing group III element raw material 2 (for example, a metal Ga, Al, or the like) is disposed in group III element raw material gas generation chamber 120, and substrate 10 is disposed on substrate holder 119 in reaction chamber 110.

Then, HCl gas 1 is introduced into group III element raw material gas generation chamber 120 via first gas introduction pipe 111. HCl gas 1 is reacted with group III element raw material 2 (for example, metal Ga melt, metal Al melt, or the like) placed in group III element raw material gas generation chamber 120 and heated by heater 131, so as to generate group III element raw material gas 3 (for example, Ga chloride gas, Al chloride gas, or the like). Group III element raw material gas 3 thus generated is introduced into reaction chamber 110 via second gas introduction pipe 112. Here, the temperature of group III element raw material 2 being heated is not particularly limited, but is preferably 400° C. or higher but 1000° C. or lower for effective generation of group III element raw material gas 3. Meanwhile, as nitride raw material gas 4, NH₃ gas is introduced into reaction chamber 110 via third gas introduction pipe 113.

Group III element raw material gas 3 and nitride raw material gas 4 thus introduced into reaction chamber 110 are reacted with each other to grow group III nitride crystal 20 on main surface 10m of substrate 10 that is being heated by heater 133. The temperature of substrate 10 being heated (hereinafter, also referred to as “crystal growth temperature”) is not particularly limited, but is preferably 900° C. or higher but 1600° C. or lower for fast growth of crystal. Meanwhile, the partial pressure (hereinafter, also referred to as P_{III}) of group III element raw material gas 3 and the partial pressure (hereinafter, also referred to as P_{N}) of nitride raw material gas 4 are not particularly limited, but group III element raw material gas 3 has a partial pressure of 0.1 kPa or greater but 50 kPa or smaller and nitride raw material gas 4 has a partial pressure of 20 kPa or greater but 90 kPa or smaller for fast growth of crystal.

Further, group III element raw material gas 3 and nitride raw material gas 4 are preferably introduced into the reaction chamber together with carrier gas to facilitate adjustment of the partial pressure of group III element raw material gas 3 and the partial pressure of nitride raw material gas 4 as well as control for rate of growth of crystal. Such carrier gas is not particularly limited as long as it is not reacted with group III element raw material gas 3 and nitride raw material gas 4, but is preferably H₂ gas, N₂ gas, Ar gas, He gas, or the like because such gas is available at low cost with high purity.

### EXAMPLES

### Example 1

### 1. Substrate Preparation Step

GaN bulk crystal was grown by the HVPE method to constitute a main surface substantially corresponding to the (0001) plane and the GaN bulk crystal thus grown had a diameter of 50.8 mm (2 inches) and had a thickness of 10 mm. By slicing it in planes parallel to the (0001) plane, five GaN substrates were obtained each having a main surface having an off-orientation angle of 0.8° or smaller relative to the (0001) plane, having a diameter of 50.8 mm (2 inches), and having a thickness of 400 μm. In this way, 100 GaN substrates were obtained from 20 pieces of GaN bulk crystal. In the main surface of each of such GaN substrates, dislocation density was 1.00×10⁸ cm⁻² measured by observation of dark spots using a CL (cathode luminescence) method.

### 2. Step of Forming the Plurality of Facets on the Main Surface of the Substrate Through Vapor Phase Etching

The GaN substrate was placed on a substrate holder in a reaction chamber of an HVPE apparatus. HCl gas having a partial pressure (P_{HCl}) of 4 kPa was introduced into the reaction chamber and the main surface thereof was subjected to vapor phase etching at 950° C. for 60 minutes. After the etching, the substrate had a thickness of 300 μm, and had a plurality of facets formed on the main surface thereof. The main surface had an average roughness Ra of 5 μm, measured using a 3D-SEM in a reference area of 100 μm×100 μm. Further, the plane orientations of the facets formed on the main surface were (11-22) and (10-12) identified by observation using X-ray diffraction, an SEM, and a laser microscope.

### 3. Group III Nitride Crystal Growth Step

On the GaN substrate's main surface having the plurality of facets formed thereon, GaN crystal was grown using the HVPE method. The crystal was grown under the following conditions: the crystal growth temperature was 1050° C., the partial pressure (P_{Ga}) of Ga chloride gas, which was group III element raw material gas, was 40.4 kPa, and the partial pressure (P_{N}) of NH₃ gas, which was nitride raw material gas, was 10.1 kPa. Under such conditions, crystal was grown for 50 hours to obtain GaN crystal having a diameter of 50.8 mm (2 inches) and a thickness of 10 mm. The crystal growth surface of the GaN crystal had a low dislocation density, 5.00×10⁵ cm⁻², which was measured through observation of dark spots using the CL method. The GaN crystal had a curvature radius of 5 m, calculated from distribution of measurements of off-orientation angles using X-ray diffraction, and therefore had a small warpage. In addition, a crack generation ratio in the 100 substrates was 5%. Here, generation of a crack indicates breakage occurring on the surface of the substrate in the form of a line of 2.0 mm or longer in length, breakage occurring thereon in the form of three or more lines of 0.5 mm-2.0 mm in length, or breakage occurring thereon in the form of 21 or more lines of 0.3 mm-0.5 mm in length. A result is shown in Table 1.

### Comparative Example 1

Comparative Example 1 is basically the same as in example 1, except that a main surface of each substrate was subjected to liquid phase etching using a phosphoric acid aqueous solution of 85% by mass at 230° C. for 3 minutes. Specifically, GaN substrates were prepared, the main surface of each substrate was etched as such, and GaN crystal was grown on the main surface etched. As a result of the etching, the substrate had a thickness of 370 μm and had a plurality of facets formed on the main surface thereof. The main surface had an average roughness Ra of 1 μm. However, the facets formed on the main surface of the substrate had surfaces in bad condition, and the plane orientations of the facets could not be specified through observation using X-ray diffraction, an SEM, and a laser microscope. With the liquid phase etching in the comparative example, an opposite main surface (rear surface) was preferentially etched as compared with the main surface that should be etched, disadvantageously. In addition, the crystal growth surface of the GaN crystal obtained had a high dislocation density, 7.00×10⁷ cm⁻², and the GaN crystal had a curvature radius of 3 m and therefore had a large warpage. A crack generation ratio was 5%. A result is shown in Table 1.

### Comparative Example 2

Comparative Example 2 is basically the same as in example 1, except that the main surface of each substrate was subjected to liquid phase etching using a phosphoric acid aqueous solution of 85% by mass at 230° C. for 10 minutes. Specifically, GaN substrates were prepared, the main surface of each substrate was etched as such, and GaN crystal was grown on the main surface etched. As a result of the etching, the substrate had a thickness of 250 μm and had a plurality of facets formed on the main surface thereof. The main surface had an average roughness Ra of 5 μm. However, the facets formed on the main surface of the substrate had surfaces in bad condition, and the plane orientations of the facets could not be specified through observation using X-ray diffraction, an SEM, and a laser microscope. With the liquid phase etching in the comparative example, an opposite main surface (rear surface) was preferentially etched as compared with the main surface that should be etched, disadvantageously. Further, a crack was generated during the crystal growth step. Although the crack was generated, the crystal growth surface of the GaN crystal obtained had a low dislocation density, 1.00×10⁶ cm⁻², and the GaN crystal had a curvature radius of 5 m and therefore had a small warpage. A result is shown in Table 1.

### Comparative Example 3

Comparative Example 3 is basically the same as in example 1, except that a main surface of each GaN substrate was polished for 120 minutes using a slurry including SiC abrasive grains having an average grain diameter of 15 μm. Specifically, GaN substrates were prepared, the main surface thereof was polished (etched), and GaN crystal was grown on the main surface thus polished (etched). As a result of the polishing (etching), the substrate had a thickness of 340 μm, and had no facet formed on the main surface thereof. The main surface had an average roughness Ra of 1.5 μm. The crystal growth surface of the GaN crystal obtained had a very high dislocation density, 1.00×10⁸ cm⁻², and the GaN crystal had a curvature radius of 3m and therefore had a large warpage. A crack generation ratio was 8%. A result is shown in Table 1.

TABLE 1

| | | Comparative | Comparative | Comparative | |
|---|---|---|---|---|---|
| | | example 1 | example 2 | example 3 | Example 1 |
| Substrate | Type | GaN | GaN | GaN | GaN |
| | Dislocation density (cm⁻²) | 1.00 × 10⁸ | 1.00 × 10⁸ | 1.00 × 10⁸ | 1.00 × 10⁸ |
| | Off-orientation angle of | 0.8° or smaller | 0.8° or smaller | 0.8° or smaller | 0.8° or smaller |
| | main surface | relative to (0001) | relative to (0001) | relative to (0001) | relative to (0001) |
| | | plane | plane | plane | plane |
| | Diameter (mm) | 50.8 | 50.8 | 50.8 | 50.8 |
| | Thickness before etching | 400 | 400 | 400 | 400 |
| | (μm) | | | | |
| | Etching method | Liquid phase | Liquid phase | Polishing | Vapor phase |
| | Etching conditions | 85% by mass | 85% by mass | Grain | HCl |
| | | H₃PO₄aq | H₃PO₄aq | diameter: | P_{HCl}: 4 kPa |
| | | 230° C. × | 230° C. × | 15 μm | 950° C. × |
| | | 3 min | 10 min | SiC abrasive | 60 min |
| | | | | grain | |
| | | | | 120 min | |
| | Thickness after etching | 370 | 250 | 340 | 300 |
| | (μm) | | | | |
| | Plane orientation of facets | — | — | Facets | (11-22) |
| | formed on main surface | | | not formed | (10-22) |
| | Average roughness Ra of | 1 | 5 | 1.5 | 5 |
| | main surface (μm) | | | | |
| Group III | Type | GaN | GaN | GaN | GaN |
| nitride | Growth method | HVPE | HVPE | HVPE | HVPE |
| crystal | Growth conditions | 1050° C. | 1050° C. | 1050° C. | 1050° C. |
| | | P_{Ga}: 40.4 kPa | P_{Ga}: 40.4 kPa | P_{Ga}: 40.4 kPa | P_{Ga}: 40.4 kPa |
| | | P_{N}: 10.1 kPa | P_{N}: 10.1 kPa | P_{N}: 10.1 kPa | P_{N}: 10.1 kPa |
| | Dislocation density (cm⁻²) | 7.00 × 10⁷ | 1.00 × 10⁶ | 1.00 × 10⁸ | 5.00 × 10⁵ |
| | Curvature radius (m) | 3 | 5 | 3 | 5 |
| | Crack generation ratio (%) | 5 | Crack | 8 | 5 |
| | | | generated in | | |
| | | | crystal growth | | |
| | | | step | | |

| | | |
|---|---|---|
| Remark | Rear surface | Rear surface |
| | preferentially | preferentially |
| | etched | etched |

In Table 1, comparative examples 1-3 and example 1 are compared. It is found that a plurality of facets having surfaces in better condition can be formed on a main surface subjected to vapor phase etching as compared with those on the main surface of a substrate subjected to liquid phase etching or polished. In this way, group III nitride crystal having a low dislocation density can be grown on the main surface of the substrate.

### Example 2

Example 2 is basically the same as in example 1 except that etching time was 30 minutes. Specifically, GaN substrates were prepared, a main surface of each substrate was etched, and GaN crystal was grown on the main surface thus etched. As a result of the etching, the substrate had a thickness of 350 μm, and had a plurality of facets formed on the main surface thereof. The main surface thereof had an average roughness Ra of 2.5 μm. The plane orientations of the facets formed on the main surface were (11-23) and (10-13). The crystal growth surface of the GaN crystal obtained had a low dislocation density, 7.00×10⁵ cm⁻², and the GaN crystal had a curvature radius of 7m and therefore had a small warpage. A crack generation ratio was 7%. A result is shown in Table 2.

### Example 3

Example 3 is basically the same as in example 1 except that etching time was 120 minutes. Specifically, GaN substrates were prepared, a main surface of each substrate was etched, and GaN crystal was grown on the main surface thus etched. As a result of the etching, the substrate had a thickness of 200 μm, and had a plurality of facets formed on the main surface thereof. The main surface thereof had an average roughness Ra of 13 μm. The plane orientations of the facets formed on the main surface were (11-22) and (10-12). The crystal growth surface of the GaN crystal obtained had a low dislocation density, 6.50×10⁵ cm⁻², and the GaN crystal had a curvature radius of 6 m and therefore had a small warpage. A crack generation ratio was 6%. A result is shown in Table 2.

### Example 4

Example 4 is basically the same as in example 1 except that etching time was 180 minutes. Specifically, GaN substrates were prepared, a main surface of each substrate was etched, and GaN crystal was grown on the main surface thus etched. As a result of the etching, the substrate had a thickness of 100 μm, and had a plurality of facets formed on the main surface thereof. The main surface thereof had an average roughness Ra of 17 μm. The plane orientations of the facets formed on the main surface were (11-21), (10-11), and (21-32). The crystal growth surface of the GaN crystal obtained had a low dislocation density, 6.50×10⁵ cm⁻², and the GaN crystal had a curvature radius of 6 m and therefore had a small warpage. A crack generation ratio was 4%. A result is shown in Table 2.

### Example 5

Example 5 is basically the same as in example 1 except that etching time was 210 minutes. Specifically, GaN substrates were prepared, a main surface of each substrate was etched, and GaN crystal was grown on the main surface thus etched. As a result of the etching, the substrate had a thickness of 50 μm, and had a plurality of facets formed on the main surface thereof. The main surface thereof had an average roughness Ra of 24 μm. The plane orientations of the facets formed on the main surface were (11-21), (10-11), (21-32), (31-43), and (32-53). The crystal growth surface of the GaN crystal obtained had a low dislocation density, 6.50×10⁵ cm⁻², and the GaN crystal had a curvature radius of 6 m and therefore had a small warpage. A crack generation ratio was 3%. A result is shown in Table 2.

TABLE 2

| | | Example 2 | Example 3 | Example 4 | Example 5 |
|---|---|---|---|---|---|
| Substrate | Type | GaN | GaN | GaN | GaN |
| | Dislocation density (cm⁻²) | 1.00 × 10⁸ | 1.00 × 10⁸ | 1.00 × 10⁸ | 1.00 × 10⁸ |
| | Off-orientation angle of | 0.8° or smaller | 0.8° or smaller | 0.8° or smaller | 0.8° or smaller |
| | main surface | relative to (0001) | relative to (0001) | relative to (0001) | relative to (0001) |
| | | plane | plane | plane | plane |
| | Diameter (mm) | 50.8 | 50.8 | 50.8 | 50.8 |
| | Thickness before etching | 400 | 400 | 400 | 400 |
| | (μm) | | | | |
| | Etching method | Vapor phase | Vapor phase | Vapor phase | Vapor phase |
| | Etching conditions | HCl | HCl | HCl | HCl |
| | | P_{HCl}: 4 kPa | P_{HCl}: 4 kPa | P_{HCl}: 4 kPa | P_{HCl}: 4 kPa |
| | | 950° C. × | 950° C. × | 950° C. × | 950° C. × |
| | | 30 min | 120 min | 180 min | 210 min |
| | Thickness after etching | 350 | 200 | 100 | 50 |
| | (μm) | | | | |
| | Plane orientation of facets | (11-23) | (11-22) | (11-21) | (11-21) |
| | formed on main surface | (10-13) | (10-12) | (10-11) | (10-11) |
| | | | | (21-32) | (21-32) |
| | | | | | (31-43) |
| | | | | | (32-53) |
| | Average roughness Ra of | 2.5 | 13 | 17 | 24 |
| | main surface (μm) | | | | |
| Group III | Type | GaN | GaN | GaN | GaN |
| nitride | Growth method | HVPE | HVPE | HVPE | HVPE |
| crystal | Growth conditions | 1050° C. | 1050° C. | 1050° C. | 1050° C. |
| | | P_{Ga}: 40.4 kPa | P_{Ga}: 40.4 kPa | P_{Ga}: 40.4 kPa | P_{Ga}: 40.4 kPa |
| | | P_{N}: 10.1 kPa | P_{N}: 10.1 kPa | P_{N}: 10.1 kPa | P_{N}: 10.1 kPa |
| | Dislocation density (cm⁻²) | 7.00 × 10⁵ | 6.50 × 10⁵ | 6.50 × 10⁵ | 6.50 × 10⁵ |
| | Curvature radius (m) | 7 | 6 | 6 | 6 |
| | Crack generation ratio (%) | 7 | 6 | 4 | 3 |

Remark

Comparing example 1 of Table 1 and examples 2-5 of Table 2 with one another, as vapor phase etching time is longer, the main surface is etched more, resulting in a large average roughness Ra in the main surface. Further, in examples 4 and 5, the crack generation ratio is reduced to 4% or smaller because it is considered that the vapor phase etching provides the substrate with a thickness of 100 μm or smaller to reduce stress/strain between the substrate and the crystal upon the crystal growth on the substrate and cooling after the crystal growth.

### Example 6

Example 6 is basically the same as in example 1 except that etching temperature was 1000° C. Specifically, GaN substrates were prepared, a main surface of each substrate was etched, and GaN crystal was grown on the main surface thus etched. As a result of the etching, the substrate had a thickness of 220 μm and had a plurality of facets formed on the main surface thereof. The main surface thereof had an average roughness Ra of 13 p.m. The plane orientations of the facets formed on the main surface were (11-21) and (10-11). The crystal growth surface of the GaN crystal obtained had a low dislocation density, 5.00×10⁵ cm⁻², and the GaN crystal had a curvature radius of 4 m. A crack generation ratio was 6%. A result is shown in Table 3.

### Example 7

Example 7 is basically the same as in example 1 except that AlN substrates were used as the substrate. Specifically, each of the AlN substrates was obtained as follows. MN bulk crystal was grown by the HVPE method to constitute a main surface substantially corresponding to the (0001) plane, having a diameter of 50.8 mm (2 inches), and having a thickness of 10 mm. By slicing it in planes parallel to the (0001) plane, the MN substrates was obtained each of which had a main surface with an off-orientation angle of 0.8° or smaller relative to the (0001) plane, had a diameter of 50.8 mm (2 inches), and had a thickness of 400 μm. The main surface of each MN substrate was etched, and GaN crystal was grown on the main surface thus etched. The main surface of the AlN substrate had a dislocation density of 5.00×10⁹ cm⁻². As a result of the etching, the substrate had a thickness of 300 μm and had a plurality of facets formed on the main surface thereof. The main surface thereof had an average roughness Ra of 5 μm. The plane orientations of the facets formed on the main surface were (11-23) and (10-13). The crystal growth surface of the GaN crystal obtained had a low dislocation density, 5.00×10⁵ cm⁻², and the GaN crystal had a curvature radius of 5 m and therefore had a small warpage. A crack generation ratio was 5%. A result is shown in Table 3.

### Example 8

Example 8 is basically the same as in example 7 except that employed etching gas for a main surface of each AlN substrate was Cl₂ gas having a partial pressure P_{Cl2} of 4 kPa and AlN crystal was grown by the HVPE method on the AlN substrates main surface having a plurality of facets formed thereon. Specifically, MN substrates were prepared, the main surface thereof was etched, and MN crystal was grown on the main surface thus etched.

As a result of the etching, the substrate had a thickness of 350 μm and had the plurality of facets formed on the main surface thereof. The main surface thereof had an average roughness Ra of 4 μm. The plane orientations of the facets formed on the main surface were (11-22) and (10-12).

The AlN crystal was grown under the following conditions: the crystal growth temperature was 1450° C., Al chloride gas, which serves as the group III element raw material gas, had a partial pressure (P_{Al}) of 40.4 kPa, and NH₃ gas, which serves as nitride raw material gas, had a partial pressure (P_{N}) of 10.1 kPa. Under such conditions, the crystal was grown for 50 hours to obtain MN crystal having a diameter of 50.8 mm (2 inches) and having a thickness of 10 mm. The crystal growth surface of the MN crystal had a low dislocation density, 5.00×10⁵ cm⁻², and the AlN crystal had a curvature radius of 6 m and therefore had a small warpage. A crack generation ratio was 8%. A result is shown in Table 3.

TABLE 3

| | | Example 6 | Example 7 | Example 8 |
|---|---|---|---|---|
| Substrate | Type | GaN | AlN | AlN |
| | Dislocation density (cm⁻²) | 1.00 × 10⁸ | 5.00 × 10⁹ | 5.00 × 10⁹ |
| | Off-orientation angle of | 0.8° or smaller | 0.8° or smaller | 0.8° or smaller |
| | main surface | relative to (0001) | relative to (0001) | relative to (0001) |
| | | plane | plane | plane |
| | Diameter (mm) | 50.8 | 50.8 | 50.8 |
| | Thickness before etching | 400 | 400 | 400 |
| | (μm) | | | |
| | Etching method | Vapor phase | Vapor phase | Vapor phase |
| | Etching conditions | HCl | HCl | Cl₂ |
| | | P_{HCl}: 4 kPa | P_{HCl}: 4 kPa | P_{Cl2}: 4 kPa |
| | | 1000° C. × | 950° C. × | 950° C. × |
| | | 60 min | 60 min | 60 min |
| | Thickness after etching | 220 | 300 | 350 |
| | (μm) | | | |
| | Plane orientations of | (11-21) | (11-23) | (11-22) |
| | facets formed on main | (10-11) | (10-13) | (10-12) |
| | surface | | | |
| | Average roughness Ra of | 13 | 5 | 4 |
| | main surface (μm) | | | |
| Group III | Type | GaN | GaN | AlN |
| nitride crystal | Growth method | HVPE | HVPE | HVPE |
| | Growth conditions | 1050° C. | 1050° C. | 1450° C. |
| | | P_{Ga}: 40.4 kPa | P_{Ga}: 40.4 kPa | P_{Al}: 40.4 kPa |
| | | P_{N}: 10.1 kPa | P_{N}: 10.1 kPa | P_{N}: 10.1 kPa |
| | Dislocation density (cm⁻²) | 5.00 × 10⁵ | 5.00 × 10⁵ | 5.00 × 10⁵ |
| | Curvature radius (m) | 4 | 5 | 6 |
| | Crack generation ratio | 6 | 5 | 8 |
| | (%) | | | |

Remark

Comparing example 1 of Table 1 and example 6 of Table 3 with each other, it is found that as the etching temperature is higher, the main surface is etched more, resulting in a larger average roughness Ra in the main surface. Meanwhile, comparing example 1 of Table 1 and examples 7 and 8 of Table 3 with one another, it was found that also when an AlN substrate was employed as the substrate instead of a GaN substrate or when AlN crystal was grown instead of GaN crystal as the crystal to be grown, crystal having a low dislocation density can be obtained by forming a plurality of facets on a main surface of a substrate through vapor phase etching and growing crystal on the main surface having the facets thus formed thereon.

### Example 9

Example 9 is basically the same as in example 1 except that GaN/sapphire substrates (template substrates) were used as the substrates and etching time was 30 minutes. In each GaN/sapphire substrate, GaN seed crystal having a thickness of 100 μm was formed on a sapphire underlying substrate having a thickness of 400 μm. Specifically, GaN/sapphire substrates were prepared, a main surface thereof was etched and GaN crystal was grown on the main surface thus etched.

The substrate of the present example was a GaN/sapphire substrate including GaN seed crystal constituting one main surface thereof and obtained by growing the GaN crystal on the (0001) plane of the sapphire substrate by the HYPE method. The main surface had an off-orientation angle of 0.8° or smaller relative to the (0001) plane and had a diameter of 50.8 mm (2 inches). The GaN seed crystal had a thickness of 100 μm, and the sapphire underlying substrate had a thickness of 400 μm. The main surface of GaN/sapphire substrate had a dislocation density of 1.00×10⁸ cm⁻². As a result of the etching of the substrate, the GaN seed crystal constituting the one main surface of the substrate had a thickness of 50 μm, and a plurality of facets were formed on the main surface of the substrate. The main surface thereof had an average roughness Ra of 2.5 μm. The plane orientations of the facets formed on the main surface were (11-23) and (10-13). The crystal growth surface of the GaN crystal obtained had a low dislocation density, 7.00×10⁵ cm⁻², and the GaN crystal had a curvature radius of 7 m and therefore had a small warpage. A crack generation ratio was 7%. A result is shown in Table 4.

### Example 10

Example 10 is basically the same as in example 9 except that as the substrates, GaN/SiC substrates (template substrates) were employed in each of which GaN seed crystal having a thickness of 100 μm was formed on an SiC underlying substrate having a thickness of 400 μm. Specifically, GaN/SiC substrates were prepared, a main surface of each GaN/SiC substrate was etched, and GaN crystal was grown on the main surface thus etched. The main surface of the GaN/SiC substrate had a dislocation density of 1.00×10⁹ cm². As a result of the etching of the substrate, the GaN seed crystal constituting the one main surface of the substrate had a thickness of 50 p.m and a plurality of facets were formed on the main surface of the substrate. The main surface thereof had an average roughness Ra of 2.5 μm. The plane orientations of the facets formed on the main surface were (11-23) and (10-13). The crystal growth surface of the GaN crystal obtained had a dislocation density of 7.00×10⁵ cm⁻², and the GaN crystal had a curvature radius of 6 m and therefore had a small warpage. A crack generation ratio was 7%. A result is shown in Table 4.

### Example 11

Example 11 is basically the same as in example 9 except that as the substrates, GaN/Si substrates (template substrates) were used in each of which GaN seed crystal having a thickness of 100 μm was formed on an Si underlying substrate having a thickness of 400 μm. Specifically, GaN/Si substrates were prepared, a main surface of each substrate was etched, and GaN crystal was grown on the main surface thus etched. The main surface of the GaN/Si substrate had a dislocation density of 8.00×10⁹ cm⁻². As a result of the etching of the substrate, the GaN seed crystal substrate constituting the one main surface of the substrate had a thickness of 50 μm, and a plurality of facets were formed on the main surface of the substrate. The main surface thereof had an average roughness Ra of 2.5 μm. The plane orientations of the facets formed on the main surface were (11-23) and (10-13). Further, the crystal growth surface of the GaN crystal obtained had a low dislocation density, 7.00×10⁵ cm⁻², and the GaN crystal had a curvature radius of 6 m and therefore had a small warpage. A crack generation ratio was 7%. A result is shown in Table 4.

TABLE 4

| | | Example 9 | Example 10 | Example 11 |
|---|---|---|---|---|
| Substrate | Type | GaN/sapphire | GaN/SiC | GaN/Si |
| | Dislocation density (cm⁻²) | 1.00 × 10⁸ | 1.00 × 10⁹ | 8.00 × 10⁹ |
| | Off-orientation angle of | 0.8° or smaller | 0.8° or smaller | 0.8° or smaller |
| | main surface | relative to (0001) | relative to (0001) | relative to (0001) |
| | | plane | plane | plane |
| | Diameter (mm) | 50.8 | 50.8 | 50.8 |
| | Thickness before etching | 100/400 | 100/400 | 100/400 |
| | (μm) | | | |
| | Etching method | Vapor phase | Vapor phase | Vapor phase |
| | Etching conditions | HCl | HCl | HCl |
| | | P_{HCl}: 4 kPa | P_{HCl}: 4 kPa | P_{HCl}: 4 kPa |
| | | 950° C. × | 950° C. × | 950° C. × |
| | | 30 min | 30 min | 30 min |
| | Thickness after etching | 50/400 | 50/400 | 50/400 |
| | (μm) | | | |
| | Plane orientation of facets | (11-23) | (11-23) | (11-23) |
| | formed on main surface | (10-13) | (10-13) | (10-13) |
| | Average roughness Ra of | 2.5 | 2.5 | 2.5 |
| | main surface(μm) | | | |
| Group III | Type | GaN | GaN | GaN |
| nitride crystal | Growth method | HVPE | HVPE | HVPE |
| | Growth conditions | 1050° C. | 1050° C. | 1050° C. |
| | | P_{Ga}: 40.4 kPa | P_{Ga}: 40.4 kPa | P_{Ga}: 40.4 kPa |
| | | P_{N}: 10.1 kPa | P_{N}: 10.1 kPa | P_{N}: 10.1 kPa |
| | Dislocation density (cm⁻²) | 7.00 × 10⁵ | 7.00 × 10⁵ | 7.00 × 10⁵ |
| | Curvature radius (m) | 7 | 6 | 6 |
| | Crack generation ratio | 7 | 7 | 7 |
| | (%) | | | |

Remark

### Example 12

Example 12 is basically the same as in example 9 except that as the substrates, GaN/GaAs substrates (template substrates) were used in each of which GaN seed crystal having a thickness of 100 μm was formed on a GaAs underlying substrate having a thickness of 400 p.m. Specifically, GaN/GaAs substrates were prepared, a main surface of each substrate was etched, and GaN crystal was grown on the main surface thus etched. The main surface of the GaN/GaAs substrate had a dislocation density of 1.00×10⁸ cm⁻². As a result of the etching of the substrate, the GaN seed crystal constituting the one main surface of the substrate had a thickness of 50 μm, and the plurality of facets were formed on the main surface of the substrate. The main surface thereof had an average roughness Ra of 2.5 μm. The plane orientations of the facets formed on the main surface were (11-23) and (10-13). Further, the crystal growth surface of the GaN crystal obtained had a low dislocation density, 7.00×10⁵ cm⁻², and the GaN crystal had a curvature radius of 5 m and therefore had a small warpage. A crack generation ratio was 7%. A result is shown in Table 5.

### Example 13

Example 13 is basically the same as in example 9 except that as the substrates, GaN/GaP substrates (template substrates) were used in each of which GaN seed crystal having a thickness of 100 μm was formed on a GaP underlying substrate having a thickness of 400 μm. Specifically, GaN/GaP substrates were prepared, a main surface of each substrate was etched, and GaN crystal was grown on the main surface thus etched. The main surface of the GaN/GaP substrate had a dislocation density of 1.00×10⁹ cm⁻². As a result of the etching of the substrate, the GaN seed crystal constituting the one main surface of the substrate had a thickness of 50 μm, and a plurality of facets were formed on the main surface. The main surface had an average roughness Ra of 2.5 μm. The plane orientations of the facets formed on the main surface were (11-23) and (10-13). Further, the crystal growth surface of the GaN crystal obtained had a dislocation density of 7.00×10⁵ cm⁻², and the GaN crystal had a curvature radius of 5 m and therefore had a small warpage. A crack generation ratio was 7%. A result is shown in Table 5.

### Example 14

Example 14 is basically the same as in example 9 except that as substrates, GaN/InP substrates (template substrates) were used in each of which GaN seed crystal having a thickness of 100 μm was formed on an InP underlying substrate having a thickness of 400 μm. Specifically, GaN/InP substrates were prepared, a main surface of each substrate was etched, and GaN crystal was grown on the main surface thus etched. The main surface of the GaN/InP substrate had a dislocation density of 1.00×10⁹ cm⁻². As a result of the etching of the substrate, the GaN seed crystal constituting the one main surface of the substrate had a thickness of 50 μm, and a plurality of facets were formed on the main surface. The main surface thereof had an average roughness Ra of 2.5 μm. The plane orientations of the facets formed on the main surface were (11-23) and (10-13). The crystal growth surface of the GaN crystal obtained had a low dislocation density, 7.00×10⁵ cm⁻², and the GaN crystal had a curvature radius of 5 m and therefore had a small warpage. A crack generation ratio was 7%. A result is shown in Table 5.

TABLE 5

| | | Example 12 | Example 13 | Example 14 |
|---|---|---|---|---|
| Substrate | Type | GaN/GaAs | GaN/GaP | GaN/InP |
| | Dislocation density (cm⁻²) | 1.00 × 10⁸ | 1.00 × 10⁹ | 1.00 × 10⁹ |
| | Off-orientation angle of | 0.8° or smaller | 0.8° or smaller | 0.8° or smaller |
| | main surface | relative to (0001) | relative to (0001) | relative to (0001) |
| | | plane | plane | plane |
| | Diameter (mm) | 50.8 | 50.8 | 50.8 |
| | Thickness before etching | 100/400 | 100/400 | 100/400 |
| | (μm) | | | |
| | Etching method | Vapor phase | Vapor phase | Vapor phase |
| | Etching conditions | HCl | HCl | HCl |
| | | P_{HCl}: 4 kPa | P_{HCl}: 4 kPa | P_{HCl}: 4 kPa |
| | | 950° C. × | 950° C. × | 950° C. × |
| | | 30 min | 30 min | 30 min |
| | Thickness after etching | 50/400 | 50/400 | 50/400 |
| | (μm) | | | |
| | Plane orientation of facets | (11-23) | (11-23) | (11-23) |
| | formed on main surface | (10-13) | (10-13) | (10-13) |
| | Average roughness Ra of | 2.5 | 2.5 | 2.5 |
| | main surface(μm) | | | |
| Group III | Type | GaN | GaN | GaN |
| nitride crystal | Growth method | HVPE | HVPE | HVPE |
| | Growth conditions | 1050° C. | 1050° C. | 1050° C. |
| | | P_{Ga}: 40.4 kPa | P_{Ga}: 40.4 kPa | P_{Ga}: 40.4 kPa |
| | | P_{N}: 10.1 kPa | P_{N}: 10.1 kPa | P_{N}: 10.1 kPa |
| | Dislocation density (cm⁻²) | 7.00 × 10⁵ | 7.00 × 10⁵ | 7.00 × 10⁵ |
| | Curvature radius (m) | 5 | 5 | 5 |
| | Crack generation ratio (%) | 7 | 7 | 7 |

Remark

As shown in examples 9-14 of Tables 4 and 5, it is recognized that also when a template substrate including GaN seed crystal on its main surface is employed, crystal having a low dislocation density can be obtained by forming a plurality of facets on the main surface of the substrate through vapor phase etching and growing GaN crystal on the main surface having the facets formed thereon.

### Example 15

Example 15 is basically the same as in example 1 except that crystal to be grown was AlGaN crystal. Specifically, GaN substrates were prepared, a main surface of each substrate was etched, and Al_{0.25}Ga_{0.75}N crystal was grown on the main surface thus etched. The crystal was grown under the following conditions: crystal growth temperature was 1050° C., Al chloride gas and Ga chloride gas, each of which was the group III element raw material gas, had partial pressures of 10.1 kPa (P_{Al}) and 30.3 kPa (P_{Ga}) respectively, and NH₃ gas, which was the nitride raw material gas, had a partial pressure (P_{N}) of 10.1 kPa. The main surface of the GaN substrate had a dislocation density of 1.00×10⁸ cm⁻². As a result of the etching of the substrate, the substrate had a thickness of 300 μm, and had a plurality of facets formed on its main surface. The main surface had an average roughness Ra of 5 p.m. The plane orientations of the facets formed on the main surface were (11-22) and (10-12). Further, the crystal growth surface of the GaN crystal obtained had a low dislocation density, 5.00×10⁵ cm⁻², and the GaN crystal had a curvature radius of 5 m and therefore had a small warpage. A crack generation ratio was 5%. A result is shown in Table 6.

### Example 16

Example 16 is basically the same as in example 1 except that employed etching gas for the main surface of the GaN substrate was Cl₂ gas. Specifically, GaN substrates were prepared, a main surface of each substrate was etched, and GaN crystal was grown on the main surface thus etched. As a result of the etching of the substrate, the substrate had a thickness of 280 μm and had a plurality of facets formed on its main surface. The main surface thereof had an average roughness Ra of 7 μm. The plane orientations of the facets formed on the main surface were (11-21) and (10-11). Further, the crystal growth surface of the GaN crystal obtained had a low dislocation density, 4.00×10⁵ cm⁻², and the GaN crystal had a curvature radius of 6 m and therefore had a small warpage. A crack generation ratio was low, 4%. A result is shown in Table 6.

### Example 17

Example 17 is basically the same as in example 1 except that employed etching gas for the main surface of the GaN substrate was H₂ gas. Specifically, GaN substrates were prepared, a main surface of each substrate was etched, and GaN crystal was grown on the main surface thus etched. As a result of the etching of the substrate, the substrate had a thickness of 350 μm, and had a plurality of facets formed on its main surface. The main surface thereof had an average roughness Ra of 4 μm. The plane orientations of the facets formed on the main surface were (11-23) and (10-13). The crystal growth surface of the GaN crystal obtained had a low dislocation density, 8.00×10⁵ cm⁻², and the GaN crystal had a curvature radius of 5 m and therefore had a small warpage. A crack generation ratio was 7%. A result is shown in Table 6.

TABLE 6

| | | Example 15 | Example 16 | Example 17 |
|---|---|---|---|---|
| Substrate | Type | GaN | GaN | GaN |
| | Dislocation density (cm⁻²) | 1.00 × 10⁸ | 1.00 × 10⁸ | 1.00 × 10⁸ |
| | Off-orientation angle of | 0.8° or smaller | 0.8° or smaller | 0.8° or smaller |
| | main surface | relative to (0001) | relative to (0001) | relative to (0001) |
| | | plane | plane | plane |
| | Diameter (mm) | 50.8 | 50.8 | 50.8 |
| | Thickness before etching | 400 | 400 | 400 |
| | (μm) | | | |
| | Etching method | Vapor phase | Vapor phase | Vapor phase |
| | Etching conditions | HCl | Cl₂ | H₂ |
| | | P_{HCl}: 4 kPa | P_{Cl2}: 4 kPa | P_{H2}: 4 kPa |
| | | 950° C. × | 950° C. × | 950° C. × |
| | | 60 min | 60 min | 60 min |
| | Thickness after etching | 300 | 280 | 350 |
| | (μm) | | | |
| | Plane orientation of facets | (11-22) | (11-21) | (11-23) |
| | formed on main surface | (10-12) | (10-11) | (10-13) |
| | Average roughness Ra of | 5 | 7 | 4 |
| | main surface (μm) | | | |
| Group III | Type | Al_{0.25}Ga_{0.75}N | GaN | GaN |
| nitride crystal | Growth method | HVPE | HVPE | HVPE |
| | Growth conditions | 1050° C. | 1050° C. | 1050° C. |
| | | P_{Al}: 10.1 kPa | P_{Ga}: 40.4 kPa | P_{Ga}: 40.4 kPa |
| | | P_{Ga}: 30.3 kPa | P_{N}: 10.1 kPa | P_{N}: 10.1 kPa |
| | | P_{N}: 10.1 kPa | | |
| | Dislocation density (cm⁻²) | 5.00 × 10⁵ | 4.00 × 10⁵ | 8.00 × 10⁵ |
| | Curvature radius (m) | 5 | 6 | 5 |
| | Crack generation ratio (%) | 5 | 4 | 7 |

Remark

Comparing example 1 of Table 1 and example 15 of Table 6 with each other, it is found that also when crystal to be grown is Al₁₋ₓGaₓN crystal (0<x<1) instead of GaN crystal, crystal having a low dislocation density can be obtained by forming a plurality of facets on a main surface of a substrate through vapor phase etching and growing crystal on the main surface thus having the facets formed thereon. Comparing example 1 of table 1 and examples 16 and 17 of Table 6 with one another, it is found that also when Cl₂ gas or H₂ gas is employed as etching gas instead of HCl gas, facets can be formed on the main surface of each substrate.

It should be understood that the embodiments and examples disclosed herein are illustrative and non-restrictive in any respect. The scope of the present invention is defined by the terms of the claims, rather than the description above, and is intended to include any modifications within the scope and meaning equivalent to the terms of the claims.

1. A method for growing group III nitride crystal, comprising the steps of:
preparing a substrate including a group III nitride seed crystal constituting one main surface thereof;
forming a plurality of facets through vapor phase etching on said main surface of said substrate; and
growing group III nitride crystal on said main surface on which said facets are formed.

2. The method for growing group III nitride crystal according to claim 1, wherein:
said main surface has an off-orientation angle of 10° or smaller relative to a (0001) plane of said group III nitride seed crystal, and
said facets include at least one geometrically equivalent crystal plane selected from a group consisting of {11-2 m} planes and {10-1n} planes, m being a positive integer, n being a positive integer.

3. The method for growing group III nitride crystal according to claim 1, wherein said vapor phase etching is performed using at least one gas selected from a group consisting of HCl gas, Cl₂ gas, and H₂ gas.

4. The method for growing group III nitride crystal according to claim 1, wherein said main surface on which said facets are formed has an average roughness Ra of 1 μm or greater but 1 mm or smaller.

5. The method for growing group III nitride crystal according to claim 1, wherein after said vapor phase etching, said substrate has a thickness of 300 μm or smaller.

6. The method for growing group III nitride crystal according to claim 1, wherein after the step of forming said plurality of facets on said main surface of said substrate, the step of growing group III nitride crystal on said main surface on which said facets are formed is performed uninterruptedly without moving said substrate.
